(19) United States
(12) Patent Application Publication
(10) Pub. No.: US 2023/0161202 A1
(43) Pub. Date: May 25, 2023

(54) DISPLAY PANEL AND DISPLAY DEVICE

(71) Applicant: Xiamen Tianma Micro-Electronics Co., Ltd., Xiamen (CN)

(72) Inventor: Xiaodong LUO, Xiamen (CN)

(73) Assignee: Xiamen Tianma Micro-Electronics Co., Ltd., Xiamen (CN)

(21) Appl. No.: 18/147,186

(22) Filed: Dec. 28, 2022

(30) Foreign Application Priority Data
Jun. 30, 2022 (CN) 202210767467.3

(51) Int. Cl. G02F 1/1339; G02F 1/1362; H01L 27/12

(52) U.S. Cl. CPC G02F 1/13396; G02F 1/13394; G02F 1/136286; H01L 27/124; G02F 2201/52; G02F 1/133512

(57) ABSTRACT

The present application is directed to display panel and display device. The display panel includes first substrate and second substrate, first signal line layer, support posts, and encapsulation glue located at one end of the non-display area away from the display area. The first signal line layer includes a first signal line located between the encapsulation glue and the display area and a second signal line located at the display area. Width of the first signal line is greater than that of the second signal line. The support posts include a main support post and an auxiliary support post. An area between the encapsulation glue and the display area is provided with main supports and auxiliary support posts. The first signal line does not overlap with the main support post and the first signal line overlaps with the auxiliary support post in a direction perpendicular to the display panel.

### CROSS-REFERENCE TO RELATED APPLICATIONS

The present application claims priority to Chinese Patent Application No. 202210767467.3, filed on Jun. 30, 2022, the content of which is incorporated herein by reference in its entirety.

### TECHNICAL FIELD

This application relates to the field of display technology, in particular to a display panel and a display device.

### BACKGROUND

Support posts are typically included in the display panel to support the space between the first and second substrates, especially in a liquid crystal display panel, and the support posts support the first and second substrates to form a liquid crystal cell to accommodate the liquid crystal layer.

In a medium-size display panel, the width of the non-display area is relatively large, and thus, it is desirable to also provide the support posts in the non-display area. However, since at least part of the non-display area has a thickness inconsistent with the thickness of the film layer in the display area, the support post in the non-display area may cause the liquid crystal cell thickness of the non-display area to be greater, thereby affecting the display effect on the edge position of the display area.

### SUMMARY

Embodiments of the present application provide a display panel and a display device.

In a first aspect, embodiments of the application provide a display panel comprising a display area and a non-display area; and the display panel comprises:
a first substrate;
a second substrate, configured opposite to the first substrate;
an encapsulation glue, configured between the first substrate and the second substrate; the encapsulation glue is located at an end of the non-display area away from the display area;
a first signal line layer, configured on a side of the first substrate facing the second substrate, and comprising a first signal line and a second signal line, wherein a width of the first signal line is greater than a width of the second signal line, the first signal line is configured on the non-display area, and the second signal line is configured on the display area; and
support posts configured between the first signal line layer and the second substrate, and comprising a main support post and an auxiliary support post, wherein a height of the auxiliary support post is less than a height of the main support post;
wherein main supports and auxiliary support posts are configured in a region between the encapsulation glue and the display area, and the first signal line is configured between the encapsulation glue and the display area;
the first signal line does not overlap with the main support post and the first signal line overlaps with the auxiliary support post in a direction perpendicular to a plane of the display panel. In a second aspect of the present disclosure, a display device including the above display panel is configured.

### BRIEF DESCRIPTION OF THE DRAWINGS

To describe the technical solutions in the embodiments of the present disclosure more clearly, the following briefly describes the accompanying drawings required to be used in the embodiments. Apparently, the accompanying drawings in the following description show merely some embodiments of the present disclosure, and a person of ordinary skill in the art may still derive other drawings from these accompanying drawings.

FIG. 1 is a cross-sectional view of a display panel provided by an embodiment of the application;

FIG. 2 is a perspective view of a main support post and an auxiliary support post in a display panel according to an embodiment of the application;

FIG. 3 is a perspective view of a main support post and an auxiliary support post in a display panel according to an embodiment of the application;

FIG. 4 is a schematic plan view of a display panel provided by an embodiment of the application;

FIG. 5 is a cross-sectional view of a partial film layer on a first substrate in a display panel according to an embodiment of the application;

FIG. 6 is a partial plan view of a display panel provided by an embodiment of the application;

FIG. 7 is a partial plan view of a display panel provided by an embodiment of the application;

FIG. 8 is a cross-sectional view of a display panel provided by an embodiment of the application;

FIG. 9 is a partial plan view of a display panel provided by an embodiment of the application;

FIG. 10 is a partial plan view of a display panel provided by an embodiment of the application;

FIG. 11 is a partial plan view of a display panel provided by an embodiment of the application;

FIG. 12 is a schematic view of a display device according to an embodiment of the present disclosure; and

FIG. 13 is a schematic view of a display device according to an embodiment of the present disclosure.

### DETAILED DESCRIPTION

For better understanding of the technical solutions of the present disclosure, the embodiments of the present disclosure are described in detail below with reference to the accompanying drawings.

It should be noted that the embodiments in the following descriptions are only a part rather than all of the embodiments in the present disclosure. All other embodiments obtained by those ordinarily skilled in the art based on the embodiments of the present disclosure should also fall within the protection scope of the present disclosure.

Terms in the embodiments of the present disclosure are merely used to describe the specific embodiments, and are not intended to limit the present disclosure. Unless otherwise specified in the context, words, such as “a”, “the”, and “this”, in a singular form in the embodiments of the present disclosure and the appended claims include plural forms.

It should be understood that the term “and/or” in this specification merely describes associations between associated objects, and it indicates three types of relationships. For example, A and/or B may indicate that A exists alone, A and B coexist, or B exists alone. In addition, the character “/” in this specification generally indicates that the associated objects are in an “or” relationship.

In this specification, it should be understood that the terms “basically”, “approximately”, “about”, “generally” and “substantially” described in claims and embodiments of the present disclosure refer to a substantially approved value, rather than an exact value, within a reasonable process operation range or tolerance range.

It should be understood that although the terms ‘first’, ‘second’ and ‘third’ can be used in the present disclosure to describe substrates, signal lines, etc., these substrates, signal lines, etc. should not be limited to these terms. These terms are used only to distinguish the substrates, signal lines, etc. from each other. For example, without departing from the scope of the embodiments of the present disclosure, a first substrate can also be referred to as a second substrate. Similarly, the second substrate can also be referred to as the first substrate.

The solutions to the problem in the related art are provided in the following disclosure. FIG. 1 is a schematic cross-sectional view of a display panel provided by an embodiment of the application.

As shown in FIG. 1, the display panel provided by the embodiments of the present application includes a display area AA and a non-display area NA. The display area AA is an area for light-emitting display, and the non-display area NA is provided at a periphery of the display area AA and mainly for arranging peripheral circuits, peripheral signal lines and encapsulation structures. Referring to FIG. 1, the display panel 001 includes a first substrate 01, a second substrate 02 and an encapsulation glue 03, the first substrate 01 is provided opposite to the second substrate 02 and the encapsulation glue 03 is provided between the first substrate 01 and the second substrate 02. The encapsulation glue 03 is provided at one end of the non-display area NA of the display panel 001 away from the display area AA, for encapsulating and fixing the first substrate 01 and the second substrate 02. It should be noted that the encapsulation glue 03 may be in direct contact with the first substrate 01 and the second substrate 02, or may be in contact with a film provided on the first substrate 01 and the second substrate 02.

In addition, the display panel 001 further includes a first signal line layer 04 provided at a side of the first substrate 01 facing the second substrate 02, i.e., the first signal line layer 04 is also provided between the first substrate 01 and the second substrate 02. Alternatively, the first signal line layer 04 is provided on the first substrate 01 and on a side of the first substrate 01 facing the second substrate 02.

The first signal line layer 04 includes a first signal line 41 provided in the non-display area NA and a second signal line 42 provided in the display area AA, and a width of the first signal line 41 is greater than a width of the second signal line 42. The first signal lines 41 may be peripheral wiring routed from the bonding area of the display panel 001 to other areas of the display panel. In this case, the length of the first signal lines 41 is generally longer and wider, such that the first signal lines 41 have less resistance and less risk of wire breakage.

Specifically, the first signal line 41 is provided in a region between the encapsulation glue 03 and the display area AA, that is, the first signal line 41 is located in a region between the encapsulation glue 03 and the display area AA.

The display panel 001 further includes a plurality of support posts 05 between the first signal line layer 04 and the second substrate 02. The support post 05 may be provided on the second substrate 02 on a side of the second substrate 02 facing the first substrate 01. In one application scenario, the support post 05 is arranged such that there is a space between the first substrate 01 and the second substrate 02 that can accommodate a liquid crystal layer, i.e., the support post 05 is arranged such that the first substrate 01 and the second substrate 02 of the display panel form a liquid crystal cell.

The display panel 001 includes a plurality of support posts 05 including a main support post 51 and an auxiliary support post 52, and the height of the auxiliary support post 52 is less than the height of the main support post 51. The secondary support post 52 and the primary support post 51 may be prepared at the same time, that is the secondary support post 52 and the primary support post 51 are on the same film layer. In addition, the auxiliary support posts 52 may also be formed in a different process step than the main support posts 51, e.g., the auxiliary support posts 52 may be formed during color resist preparation in the display panel 001, i.e., the auxiliary support posts 52 may be formed by stacking color resists.

In this embodiment, as shown in FIG. 1, the area between the encapsulation glue 03 and the display area AA is provided with a plurality of main supports 51 and a plurality of sub-supports 52, i.e., in the non-display area NA of the display panel 001, the area between the encapsulation glue 03 and the display area AA is provided with a plurality of main supports 51 and a plurality of sub-supports 52 for supporting the non-display area NA of the display panel 001.

In this embodiment, in the direction Z perpendicular to the plane of the display panel 001, the first signal lines 41 do not overlap the main support posts 51, and the first signal lines 41 overlap the auxiliary support posts 52. That is, when the width of the first signal lines 41 in the non-display area NA of the display panel 001 is large and the support post 05 cannot be avoided, the first signal lines 41 can be misaligned with the main support post 51.

By misaligning the first signal lines 41 from the main support posts 51, the first signal lines 41 with larger widths do not overlap the main support posts 51, and the problem of the main support posts 51 being provided above the first signal lines 41 such that the distance between the first substrate 01 and the second substrate 02 in the non-display area NA is increased can be avoided. When the display panel 001 is a liquid crystal display panel that further includes a liquid crystal layer between the first substrate 01 and the second substrate 02, the problem of edge display yellowing of the display panel 001 caused by an increase in the thickness of the liquid crystal cell near the area of the first signal line 41 can be avoided by adopting the inventive concepts of the present application.

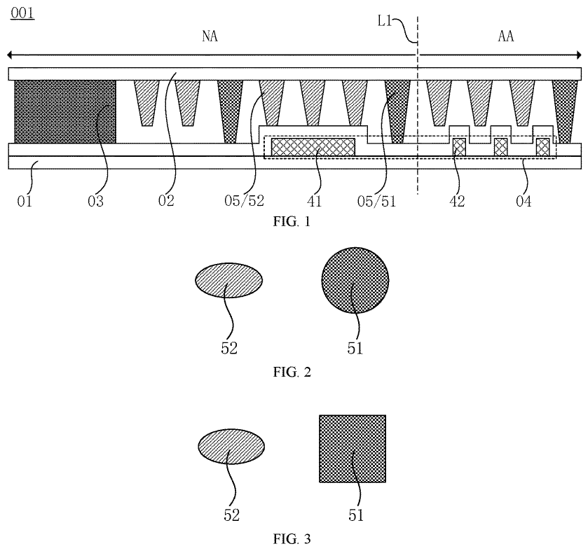

FIG. 2 is a perspective view of a main support post and an auxiliary support post in a display panel according to an embodiment of the application.

In one embodiment of the present application, the orthographic projection shape of the auxiliary support post 52 is elliptical and the orthographic projection shape of the main support post 51 is circular in a direction perpendicular to the plane of the display panel. The end surface shape of the secondary support post 52 can be configured to be elliptical, which increases the support area of the secondary support post 52. At the same time, the end surface shape of the primary support post 51 can be configured to be circular, and the circular projection facilitates reducing the impact on the light-transmitting region when the primary support post 51 is flared, avoiding regular dark spots when displaying the panel display.

FIG. 3 is a perspective view of a main support post and an auxiliary support post in a display panel according to an embodiment of the application.

In one embodiment of the present application, the orthographic projection shape of the auxiliary support post 52 is elliptical and the orthographic projection shape of the main support post 51 is square in a direction perpendicular to the plane of the display panel. Setting the end surface shape of the secondary support post 52 to be elliptical may increase the support area of the secondary support post 52; while setting the end surface shape of the primary support post 51 to be square may make the support area of the main support post 51 to be larger.

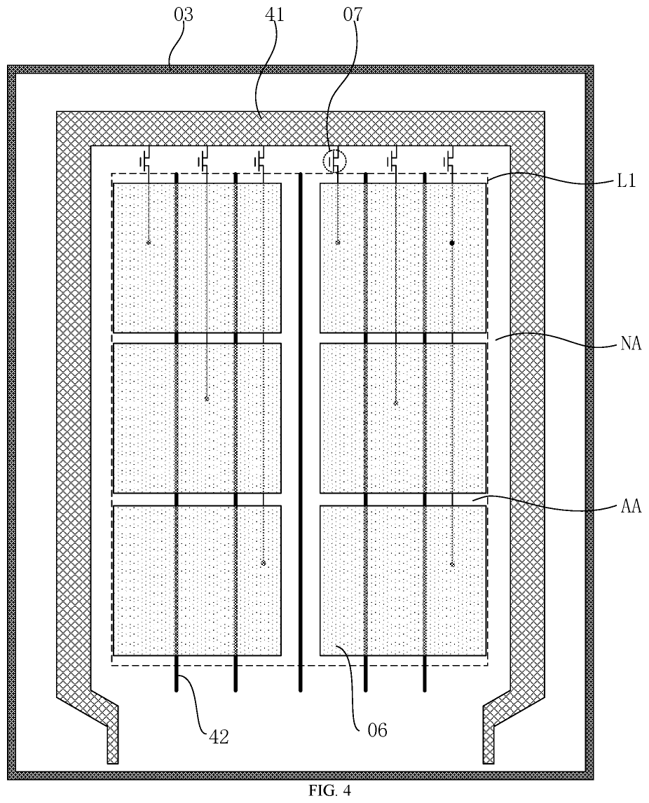

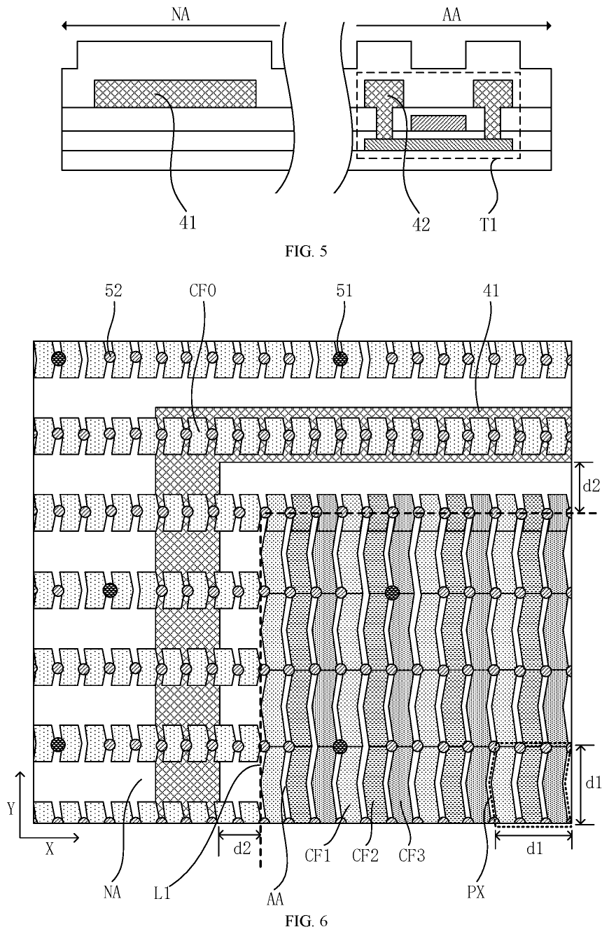

FIG. 4 is a schematic plan view of a display panel provided by an embodiment of the application. In one embodiment of the present application, the first signal line 41 is located in an area that at least partially surrounds the display area AA. For example, as shown in FIG. 4, the first signal line 41 may semi-surround the display area AA, and the first signal line 41 may be peripheral wiring routed from the bonding area of the display panel 001 to other areas of the display panel, and the length of the first signal line 41 is typically longer and wider.

In one implementation of the present embodiment, as shown in FIG. 4, the display panel 001 further includes a common electrode 06 provided between the first substrate 01 and the second substrate 02, and the common electrode 06 is electrically connected to the first signal line 41, i.e., the first signal line 41 may be a common voltage signal line for providing a common voltage to the common electrode 06. As shown in FIG. 2, the first signal line 41 and the common electrode 06 are electrically connected to the upper frame opposite to the lower frame through the control switch 07.

Specifically, as shown in FIG. 4, the display panel 001 may include a plurality of common electrodes 06, and the common electrodes 06 may be multiplexed as touch electrodes. That is, the common electrode 06 receives the common voltage transmitted by the first signal line 41 through the conductive control switch 07 in the display stage of the display panel 001, and the common electrode 06 receives the touch-related signal in the touch stage of the display panel 001. It should be noted that the plurality of common electrodes 06 can be simultaneously connected to a common voltage in the display stage, that is, the control switches 07 respectively electrically connected to the common electrodes 06 are simultaneously turned on in the display stage. It should be further noted that the display panel 001 may include one first signal line 41 or may include two or more first signal lines 41.

The width of the first signal line 41 is in a range of 60 μm-200 μm. Preferably, the width of the first signal line 41 is about 100 μm.

By using the inventive concept of the present application, the width of the first signal line 41 providing the common voltage signal to the common electrode 06 can be set wider to reduce the voltage drop on the first signal line 41, thereby bringing the common voltage signal received by the common electrode 06 closer to a preset value, improving the contrast ratio of the display panel. FIG. 5 schematically shows a cross-sectional view of a portion of a film layer on a first substrate in a display panel according to an embodiment of the present disclosure.

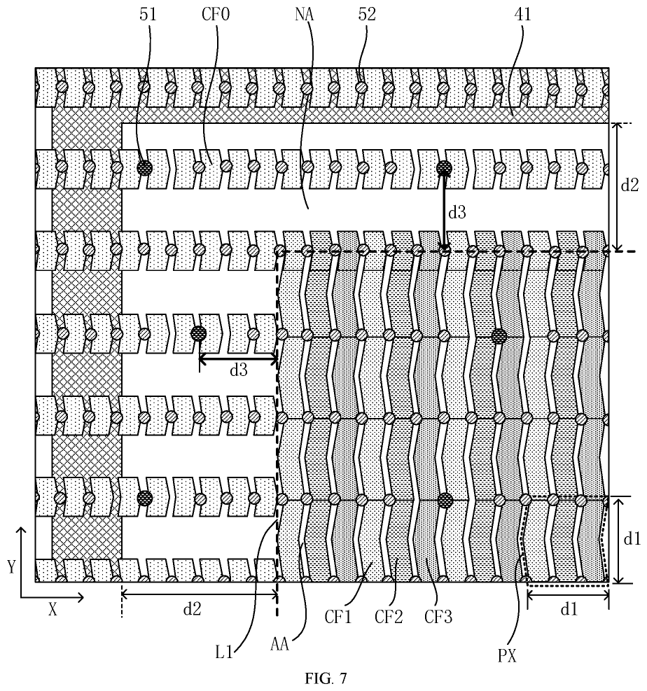

As shown in FIG. 5, the display panel 001 provided by embodiments of the present application includes a plurality of transistors T1, and the second signal line 42 is electrically connected to at least some sources of the transistors T1. The thickness of the second signal trace 42 and the first signal trace 41 is typically about 0.5 FIG. 6 is a partial plan view of a display panel according to an embodiment of the application, and FIG. 7 is a partial plan view of a display panel according to an embodiment of the application. As shown in FIGS. 6 and 7, the display area AA in the display panel 001 according to embodiments of the present application includes a plurality of pixels PX including a plurality of sub-pixels of different colors. The sub-pixels of different colors respectively include different colors, for example, the pixel PX includes a red sub-pixel, a green sub-pixel, and a blue sub-pixel, and the red sub-pixel includes a red color resistor CF1, the green sub-pixel includes a green color resistor CF2, and the blue sub-pixel includes a blue color resistor CF3.

The width of the pixel PX may be d1, the width of the pixel PX may be the width of the pixel PX along the arrangement direction of the sub-pixels included therein, or the width of the pixel PX may be the width of the pixel PX along the arrangement direction perpendicular to the sub-pixels included therein. Taking the sub-pixels included in the pixel PX arranged along the direction X as an example, the width of the pixel PX along the direction X may be d1, or the width of the pixel PX along the direction Y may be d1.

In addition, a minimum distance between an edge of the first signal line 41 near one side of the display area AA in the non-display area NA and the display area AA is d2. That is, the minimum distance between the boundary line L1 located between the display area AA and the non-display area NA and the edge of the first signal line 41 near one side of the display area AA is d2. In one embodiment of the present application, as shown in FIG. 6, 2d1≥d2 and the area between the first signal line 41 and the display area AA does not include the main support posts 51. That is, when the width of the area between the first signal line 41 and the display area AA is less than or equal to twice the width of the pixel PX, the main support post 51 is not provided in this area. If the main support post 51 provided in the non-display area NA is too close to the display area AA, the cell thickness in the area where the display area AA is close to the non-display area NA is increased, affecting the display effect near the edge of the display area AA. When the width of the area between the first signal line 41 and the display area AA is small, the main support post 51 is not provided in this area, and the above-mentioned problem can be solved effectively.

In one embodiment of the present application, as shown in FIG. 7, d2≥2d1 and the area between the first signal line 41 and the display area AA includes a main support post 51. That is, when the width of the area between the first signal line 41 and the display area AA is greater than or equal to twice the width of the pixel PX, the main support post 51 is provided in this area.

It has been found by the inventors that when the width of the area between the first signal line 41 and the display area AA is greater than or equal to twice the width of the pixel PX, the main support post 51 is provided in this area, and the problem that the display effect is affected by the increase of the box thickness near the edge of the display area AA will not exist.

In addition, when the width of the area between the first signal line 41 and the display area AA is large, if the main support post 51 is not provided, and the cell thickness reduction issue occurs. At this time, if a liquid crystal layer is provided between the first substrate 01 and the second substrate 02, the display panel 001 is bluish near the edge.

In one implementation of this embodiment, as shown in FIG. 7, a minimum distance between the main support post 51 and the display area AA is d3, where d3≥d1. That is, among the plurality of main support posts 51 provided between the area where the first signal line 41 is located and the display area AA, a distance between the main support post closest to the display area AA and the display area AA is greater than or equal to a width of one pixel PX.

That is, when the width of the area between the first signal line 41 and the display area AA is greater than or equal to twice the width of the pixel PX, although the main support posts 51 are provided in the area, the minimum distance between the main support posts 51 and the display area AA is also greater than or equal to the width of one pixel PX, which ensures that the cassette thickness near the area is not thinned and not thickened.

In one embodiment of the present application, as shown in FIGS. 1 and 6, an area of the first signal line 41 away from the display area AA includes a main support post 51. Since the width of the first signal line 41 is large and the area where the first signal line 41 is located is not provided with the main support post 51, the main support post 51 provided on the side of the first signal line 41 away from the display area AA is to ensure the cell thickness at the non-display area NA location, which would not influence the cell thickness of the display area AA location.

In one implementation, as shown in FIG. 1, in a region where the first signal line 41 is away from the display area AA, it is provided with support post 05 which comprises a main support post 51 in the support post 05 near the first signal line 41. That is, in a side of the first signal line 41 away from the display area AA, at least one main support post 51 is provided close to the first signal line 41, and the auxiliary support post 52 is not included between the at least one main support post 51 and the first signal line 41.

In one embodiment of the present application, as shown in FIG. 6 and FIG. 7, not only the display area AA includes a plurality of color resists, but also the non-display area NA includes a plurality of color resists. The display area AA includes color resists of different colors, for example, as shown in 6 and FIG. 7, the display area AA includes a red color resistor CF1, a green color resistor CF2, and a blue color resistor CF3. The non-display area NA includes a plurality of color resists CF0 of the same color, and the color resists CF0 of the same color are provided in the non-display area NA, and it is easy to control the thickness of the film layer on the second substrate 02 in the non-display area NA to coincide with the thickness of the film layer on the second substrate 02 in the display area AA.

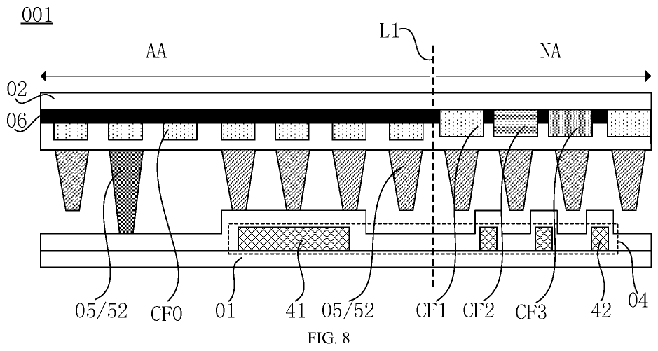

FIG. 8 is a schematic cross-sectional view of a display panel provided by an embodiment of the application.

As shown in FIG. 8, a side of the second substrate 02 facing the first substrate 01 includes a black matrix 06 including a plurality of openings and the openings are located in the display area AA, and the openings are filled with color resists. That is, the color resist provided in the display area AA is at least partially filled in the opening of the black matrix 06, and the opening provided in the black matrix 06 in the display area AA may allow the light to be emitted after passing through the color resist, thereby realizing a color display.

Also, the black matrix 06 is opened without the opening in the non-display area NA, i.e., the portion of the black matrix 06 in the non-display area NA is continuous, so as to prevent the peripheral wiring and the peripheral circuits in the non-display area NA from being visible to the human eye.

The ratio of the area of the color resist CF0 in the non-display area NA to the area of the color resist in the display area AA is 0.4 to 0.6. As shown in FIGS. 6-8, the area of the color resist CF0 provided in the non-display area NA is smaller relative to the area of the color resist provided in the display area AA.

Since the portion of the color resist in the display area AA is filled in the opening of the black matrix 06, and the color resist in the non-display area NA is completely provided on the black matrix 06, if the color resist area in the non-display area NA is the same as the color resist area in the display area AA, the sum of the thickness of the color resist in the non-display area NA and the thickness of the black matrix 06 is greater than the sum of the thickness of the color resist in the display area NA and the thickness of the black matrix. The inventors found that the sum of the thickness of the color resist in the non-display area NA and the thickness of the black matrix in the display area AA is substantially the same as the sum of the thickness of the color resist and the thickness of the black matrix in the display area AA when the area of the color resist provided in the non-display area NA is 0.4 times to 0.6 times the area of the color resist provided in the display area AA.

It should be noted that the density of the drag in the display area AA may be the same as that in the non-display area NA.

In one embodiment of the present application, the non-display area NA includes a plurality of reds, i.e., the reds CF0 in the non-display area NA and the reds CF0 in the display area AA are the same, and the shapes of the reds CF0 in the non-display area NA and the reds CF0 in the display area AA may be only different. Since there is a difference in the thicknesses of the red, green and blue color resists CF1, CF2 and CF3 provided in the display area AA, and the thickness of the red color resist CF1 is between the thickness of the green color resist CF2 and the thickness of the blue color resist CF3, the thickness difference between the thickness of the display area AA and the thickness of the blue color resist CF3 provided in the non-display area NA can be minimized.

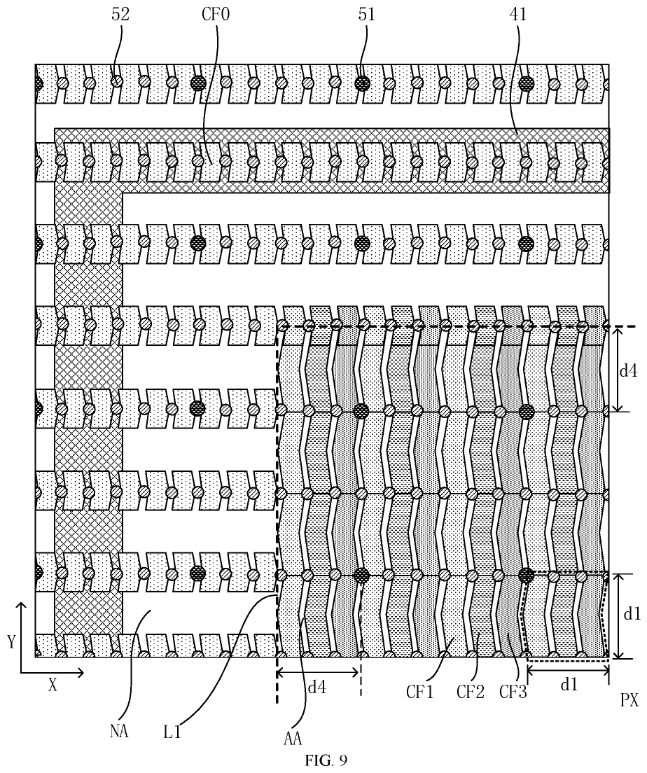

In one embodiment of the present application, as shown in FIGS. 1 and 8, the boundary line L1 between the display area AA and the non-display area NA does not include the main support post 51. That is, the main support post 51 is provided away from an interface between the display area AA and the non-display area NA. Since the black matrix 06 provided in the display area NA includes an opening and the black matrix 06 provided in the display area AA does not include an opening, the film layer on the second substrate 02 is relatively thick at the boundary between the display area AA and the non-display area NA after the color resist is provided, so it is not desirable to dispose the main support posts 51, such that the main support posts 51 of the area are prevented from significantly increasing the cell thickness near the edge position of the display area AA. FIG. 9 is a partial plan view of a display panel provided by an embodiment of the application. In one embodiment of the present application, as shown in FIG. 9, the display area AA is provided with a plurality of main support post 51 and a plurality of auxiliary support post 52. The minimum distance between the main support post 51 and the non-display area NA is d4, and d4=d1. That is, among the main support posts 51 in the display area AA, a minimum distance between a portion of the main support posts 51 closest to the non-display area NA and the non-display area NA is equal to the width of the pixel PX. The equation d4=d1 means that d4 and d1 are substantially equal, rather than absolutely equal, within error and process precision. In some embodiments, the substantially equal means+/−5% of the stated dimensions.

In the present embodiment, the main support post 51 is provided at a position having one pixel PX width away from the edge of the display area AA, and it is able to ensure the thickness of the liquid crystal cell near the position of the edge of the display area AA in the display panel 001, so as to prevent the change in the thickness of the liquid crystal cell from affecting the display effect of the display panel 001.

In one aspect of the present embodiment, the pixel PX includes a red sub-pixel, a green sub-pixel, and a blue sub-pixel, the red sub-pixel includes a red color resist CF1, the green sub-pixel includes a green color resist CF2, and the blue sub-pixel includes a blue color resist CF3. The main support post 51 with the smallest distance to the non-display area NA in the display area AA is provided between the region where the red sub-pixel is located and the region where the blue sub-pixel is located, i.e., provided in the main support post 51 of the display area AA, and the main support post 51 closest to the non-display area NA is provided between the region where the red color resist CF1 is located and the region where the blue color resist CF3 is located.

The end surface area of the main support post 51 is typically greater than the end surface area of the auxiliary support post 52, and thus the effect of the main support post 51 on the display brightness of the sub-pixel is greater than the effect of the auxiliary support post 52 on the display brightness of the sub-pixel. In addition, since the display brightness of the green sub-pixel is the brightest, if the display brightness is affected, the white balance of the display panel 001 would be affected more. For the above reasons, in the present technical solution, the main support post 51 is disposed between the red sub-pixel and the blue sub-pixel, avoiding the influence of the main support post 51 on the display brightness of the green sub-pixel. Therefore, the present disclosure can be used to prevent the display problem of the edge area of the display area AA from aggravation, and guarantee the display effect of the edge of the display area AA.

In one aspect corresponding to this embodiment, among the main support posts 51 at the display area AA, the main support posts 51 at the of the periphery of the display area AA are provided at the same minimum distance to the non-display area NA. As shown in FIG. 9, in the display area AA, the support post 05 arranged along a direction X constitute support post rows and a minimum distance between the main support post 51 closest to the non-display area NA and the non-display area NA in each support post row is d4, and the support post 05 arranged along the direction Y constitute support post columns and a minimum distance between the main support post 51 closest to the non-display area NA and the non-display area NA in each support post row is d4.

In one embodiment of the present application, as shown in FIG. 9, a plurality of main supports 51 and a plurality of sub-supports 52 are provided in the display area AA and in the non-display area NA. The number of the auxiliary support posts 52 provided adjacent to each other along the first direction and respectively between the two main support posts 51 on either side of the first signal line 41 is n1; the number of the auxiliary support posts 52 provided adjacent to each other along the first direction in the display area AA is n2; where n1=n2. The first direction is perpendicular to the extending direction of the first signal lines 41.

For example, as shown in FIG. 9, the first signal line 41 in the non-display area NA on the left side of the display panel 001 extends along the direction Y, and 5 main support posts 52 are provided between two main support posts 51 on both sides of the portion of the signal line 41 and adjacent to each other along the direction X, and 5 main support posts 52 are also provided between two main support posts 51 in the display area AA and adjacent to each other along the direction X. The direction X is perpendicular to the direction Y.

For example, as shown in FIG. 9, the first signal line 41 in the non-display area NA on the upper side of the display panel 001 extends along the direction X, and 1 auxiliary support post is provided between two main support posts 51 at two sides of the portion of the signal line 41 and adjacent to each other along the direction Y, and 1 auxiliary support post 52 is also provided between two main support posts 51 adjacent to each other along the direction Yin the display area AA. The direction X is perpendicular to the direction Y.

In one aspect of the present embodiment, the arrangement regulation of the main support posts 51 and the auxiliary support posts 52 in the display area AA and the non-display area NA is consistent. In all of the support post 05 in the display area AA and the non-display area NA of the display panel 001, the support post 05 arranged along the direction X constitute support post rows, and the support post 05 arranged along the direction Y constitute support post columns. In the support post row containing the primary support posts 51, the primary support posts 51 are arranged periodically with the auxiliary support posts 52; other support post rows include only primary support posts 51 or only auxiliary support posts 52. In the support post column containing the auxiliary support posts 52, the primary support posts 51 are arranged periodically with the auxiliary support posts 52; other posts include only primary support posts 51 or only auxiliary support posts 52. It should be understood that the non-display area NA and the display area AA adopt the same design of the support post 05, and the first signal line 41 is designed to avoid the main support post 51 in the non-display area NA. The present disclosure can be used to improve the display effect of the edge position of the display area AA without increasing the design difficulty of the support post 05.

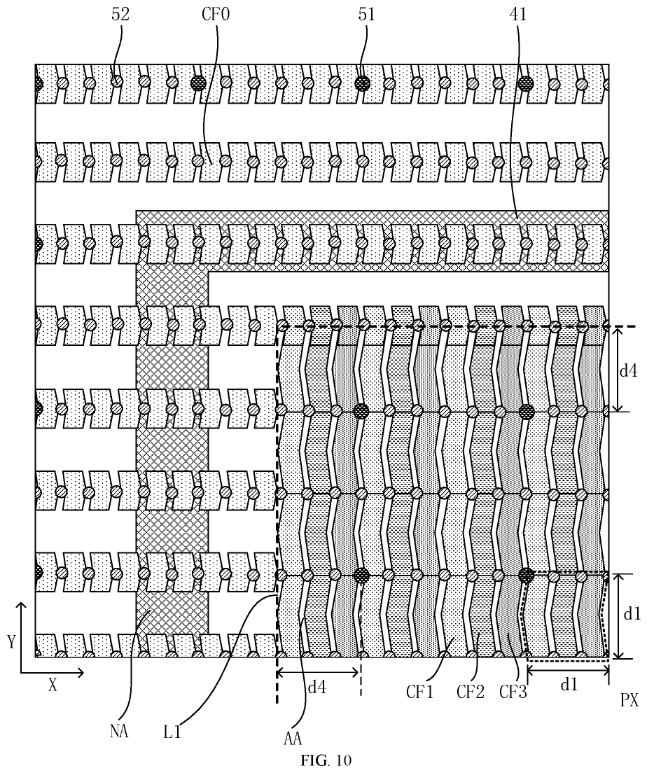

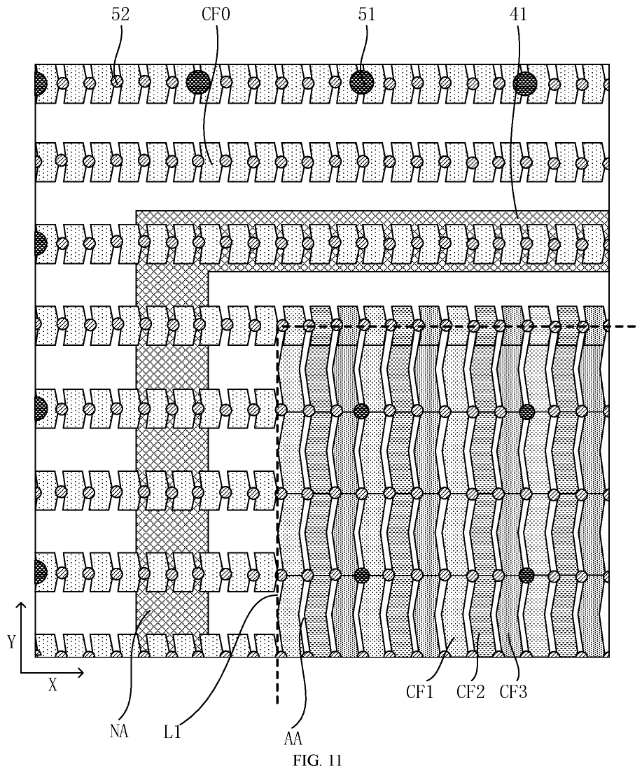

FIG. 10 is a partial plan view of a display panel provided by an embodiment of the application. In one embodiment of the present application, as shown in FIG. 10, a plurality of main supports 51 and a plurality of sub-supports 52 are provided in the display area AA and in the non-display area NA. The number of the auxiliary support posts between the two main support posts 51 provided adjacently along the first direction and respectively at two sides of the first signal line 41 is n1; the number of the auxiliary support posts 52 between the two main support posts 51 provided adjacently along the first direction in the display area AA is n2; where n1≥n2. The first direction is perpendicular to the extending direction of the first signal lines 41. That is, the density of the main support posts 51 in the non-display area NA is relatively small, which is conducive to realize that the first signal lines 41 in the non-display area NA are not overlapped with the main support posts 51.

In one aspect of the present embodiment, where n1=2*n2+1.

For example, as shown in FIG. 10, the first signal line 41 in the non-display area NA on the left side of the display panel 001 extends along the direction Y, and there are 11 main support posts 52 between two main support posts 51 on either side of the portion of the signal line 41 and adjacent along the direction X, and there are 5 main support posts 52 between two main support posts 51 adjacent along the direction X in the display area AA. The direction X is perpendicular to the direction Y.

For example, as shown in FIG. 10, the first signal line 41 in the non-display area NA on the upper side of the display panel 001 extends along the direction X, and there are 3 main support posts between two main support posts 51 at two sides of the portion of the signal line 41 and adjacent to each other along the direction Y, and there are 1 main support posts 52 between two main support posts 51 adjacent to each other along the direction Y in the display area AA. The direction X is perpendicular to the direction Y.

In one aspect of this embodiment, the arrangement regulation of the main support post 51 and the auxiliary support post 52 in the non-display area NA is consistent with the display area AA except for the area of the first signal line 41. As shown in FIG. 10, among all the support post 05 in the display area AA and the non-display area NA of the display panel 001, the support post 05 arranged along the direction X constitute support post rows, and the support post 05 arranged along the direction Y constitute support post column. In the support post row containing the primary support post 51, the primary support post 51 is arranged periodically with the auxiliary support post 52, ignoring the absence of the primary support post 51 at the location of the first signal line 41; only the primary support post 51 or only the auxiliary support post 52 is included in other support post rows. In the column containing the auxiliary support posts 52, the primary support posts 51 are arranged periodically with the auxiliary support posts 52, ignoring the absence of the primary support posts 51 at the location of the first signal line 41; only the primary support posts 51 or only the auxiliary support posts 52 are included in the other column.

It should be understood that the non-display area NA adopts the same design of the support post 05 as the display area AA except that the main support post 51 at the position of the first signal line 41 is replaced by the auxiliary support post 52. The present application can be used to improve the display effect of the edge position of the display area AA; the design difficulty of the support post 05 is not substantially increased compared to the design difficulty of the support post 05 in the prior art.

FIG. 11 is a partial plan view of a display panel provided by an embodiment of the application. In one aspect of this embodiment, as shown in FIG. 11, in the non-display area NA, the front projection area of the main support post 51 adjacent to the first signal line 41 is S1; in the display area, the front projection area of the main support post 51 is S2; where S1≥S2. That is, when the projection area of the main support posts 51 located in the non-display area NA and adjacent to the first signal line 41 is greater than the projection area of the main support posts 51 in the display area AA, the supporting force of the main support posts 51 on the first substrate 01 and the second substrate 02 in the non-display area NA can be increased by increasing the area of the main support posts 51 in the non-display area NA.

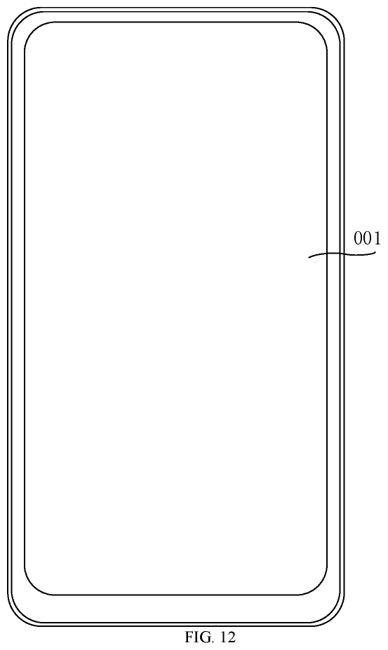

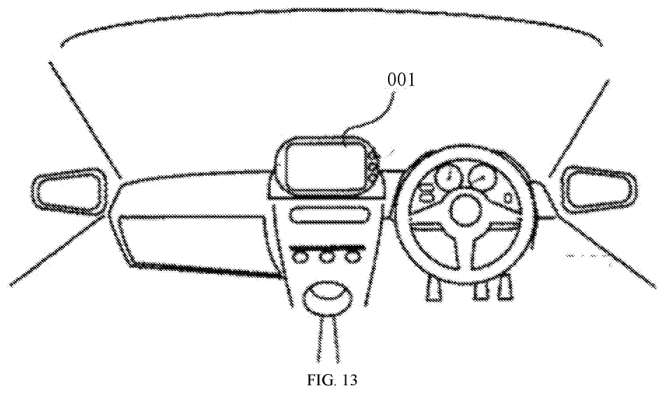

FIG. 12 is a schematic view of a display device according to an embodiment of the application, and FIG. 13 is a schematic view of a display device according to an embodiment of the application.

The display device provided by embodiments of the present application includes a display panel 001 as provided by any of the embodiments described above.

As shown in FIG. 12, the display device provided by the embodiment may be a mobile phone, or the display device provided by the embodiment may be a computer or a television.

As shown in FIG. 13, the display panel 001 provided by the embodiment of the present application may be an in-vehicle display panel, and since the width of the non-display area NA of the in-vehicle display panel is generally larger, the in-vehicle display panel using the inventive concepts of the present application may have better display performance. Accordingly, the display device provided by the embodiments of the present disclosure may also be an in-vehicle display device. When the width of the first signal lines 41 of the non-display area NA of the display panel 001 is large and the support posts 05 cannot be avoided, the first signal lines 41 can be misaligned with the main support posts 51. By misaligning the first signal lines 41 from the main support posts 51, the first signal lines 41 with larger widths do not overlap the main support posts 51, and the problem of the main support posts 51 being provided above the first signal lines 41 such that the distance between the first substrate 01 and the second substrate 02 in the non-display area NA is increased. When the display device is a liquid crystal display device, the edge display yellowing problem caused by the increase in the thickness of the liquid crystal cell near the area of the first signal line 41 can be avoided.

It is to be understood that the foregoing is only illustrative of the preferred embodiments of the application, and is not intended to limit the application. Any modifications, equivalent replacements, improvements, etc. made within the spirit and principles of the present application shall be considered to be within the scope of the present application.

What is claimed is:

1. A display panel having a display area and a non-display area, wherein the display comprises:
a first substrate;
a second substrate, configured opposite to the first substrate;
an encapsulation glue, configured between the first substrate and the second substrate; the encapsulation glue is located at an end of the non-display area away from the display area;
a first signal line layer, configured on a side of the first substrate facing the second substrate, and comprising a first signal line and a second signal line, wherein a width of the first signal line is greater than a width of the second signal line, the first signal line being configured on the non-display area, and the second signal line being configured on the display area; and
support posts configured between the first signal line layer and the second substrate, and comprising a main support post and an auxiliary support post, wherein a height of the auxiliary support post is less than a height of the main support post;
wherein the main support post and the auxiliary support post are configured in a region between the encapsulation glue and the display area, and the first signal line is configured between the encapsulation glue and the display area; and
wherein the first signal line does not overlap with the main support post and the first signal line overlaps with the auxiliary support post in a direction perpendicular to a plane of the display panel.

2. The display panel according to claim 1, wherein the first signal line is located at an area least partially around the display area.

3. The display panel according to claim 2, further comprising a common electrode configured between the first substrate and the second substrate, wherein
the common electrode is electrically connected to the first signal line.

4. The display panel according to claim 1, wherein the display area comprises pixels, each of the pixels comprises sub-pixels of different colors, and the width of the pixels is d1; and
a minimum distance between an edge of the first signal line close to the display area and the display area is d2, and 2d2≥d1;
the area between the first signal line and the display area does not include the main support post.

5. The display panel according to claim 1, wherein the display area comprises pixels, and the pixels comprise sub-pixels of different colors, and the width of the pixels is d1,
wherein a minimum distance between an edge of the first signal line close to the display area and the display area is d2, and d2≥2d1, and
an area between the first signal line and the display area is configured with the main support post.

6. The display panel according to claim 5, wherein a minimum distance between the main support post which is configured on the area between the first signal line and the display area and the display area is d3, and d3≥d1.

7. The display panel according to claim 1, wherein the display area comprises pixels, and the pixels comprise sub-pixels of different colors, and the width of the pixels is d1; and
wherein the display area is configured with main support posts and auxiliary support posts; and a minimum distance between the main support posts and the non-display area is d4, d4=d1 configured in the main support posts of the display area.

8. The display panel according to claim 7, wherein each of the pixels includes a red sub-pixel, a green sub-pixel, and a blue sub-pixel; and
one support post that is closest to the non-display area in the display area is configured between an area where the red sub-pixel is located and an area where the blue sub-pixel is located; or
wherein a minimum distance between each of the main support posts configured on a periphery of the display area and the non-display area is equal to each other.

9. The display panel according to claim 1, wherein the display area is configured with the main support posts and auxiliary support posts;
n1 auxiliary support posts are configured between two main support posts which are arranged along a first direction adjacently and located respectively on two sides of the first signal line, and the first direction is perpendicular to an extending direction of the first signal line; and
n2 auxiliary support posts are configured between two main support posts configured along the first direction adjacently in the display area, and n1≥n2.

10. The display panel according to claim 9, wherein n1=2*n2+1.

11. The display panel according to claim 9, wherein the main support posts and the auxiliary support posts are arranged in a same manner in the display area and the non-display area, except for the area where the first signal line is located.

12. The display panel according to claim 9, wherein an orthographic projection area of the main support post adjacent to the first signal line in the non-display area is S1; and wherein an orthographic projection area of the main support post in the display area is S2; and S1≥S2.

13. The display panel according to claim 1, wherein the display area is configured with the main support posts and the auxiliary support posts;
n1 auxiliary support posts are configured between two main support posts which are arranged along a first direction adjacently and located respectively on two sides of the first signal line, and the first direction is perpendicular to an extending direction of the first signal line; and
n2 auxiliary support posts are configured between two main support posts configured along the first direction adjacently in the display area, and n1=n2.

14. The display panel according to claim 13, wherein the main support post and the auxiliary support posts are arranged in a same manner in the display area and the non-display area.

15. The display panel according to claim 1, wherein an area of the first signal line away from a side of the display area is configured with the main support post.

16. The display panel according to claim 15, wherein among the support posts provided on the area of first signal line away from a side of the display area, the support post adjacent to the first signal line comprises the main support post.

17. The display panel according to claim 1, wherein the main support post is not configured on a boundary between the display area and the non-display area.

18. The display panel according to claim 1, wherein the display area comprises color resists of different colors, and the non-display area comprises color resists of the same color; and
wherein a side of the second substrate facing the first substrate comprises a black matrix, the black matrix comprises openings located in the display area, and the openings are filled with the color resists;
a ratio of a color resist area in the non-display area to a color resist area in the display area is 0.4 to 0.6.

19. The display panel according to claim 18, wherein the non-display area comprises red resists.

20. A display device comprising a display panel having a display area and a non-display area, wherein the display comprises:
a first substrate;
a second substrate, configured opposite to the first substrate;
an encapsulation glue, configured between the first substrate and the second substrate; the encapsulation glue is located at an end of the non-display area away from the display area;
a first signal line layer, configured on a side of the first substrate facing the second substrate, and comprising a first signal line and a second signal line, wherein a width of the first signal line is greater than a width of the second signal line, the first signal line is configured on the non-display area, and the second signal line is configured on the display area; and
support posts configured between the first signal line layer and the second substrate, and comprising a main support post and an auxiliary support post, wherein a height of the auxiliary support post is less than a height of the main support post;
wherein the main support post and the auxiliary support post are configured in a region between the encapsulation glue and the display area, and the first signal line is configured between the encapsulation glue and the display area; and
the first signal line does not overlap with the main support post and the first signal line overlaps with the auxiliary support post in a direction perpendicular to a plane of the display panel.
